(19) United States
(12) Patent Application Publication
(10) Pub. No.: US 2024/0008226 A1
(43) Pub. Date: Jan. 4, 2024

(54) METHOD AND APPARATUS FOR REAL TIME, IN-SITU IMMERSION COOLANT CHARACTERIZATION AND FILTRATION SYSTEM CONTROL IN RESPONSE THERETO

(71) Applicant: Intel Corporation, Santa Clara, CA (US)

(72) Inventors: Je-Young CHANG, Tempe, AZ (US); Rajiv MONGIA, Portland, OR (US); Sandeep AHUJA, Portland, OR (US)

(21) Appl. No.: 18/238,849

(22) Filed: Aug. 28, 2023

(51) Int. Cl. H05K 7/20

(52) U.S. Cl. CPC H05K 7/20381; H05K 7/20281; H05K 7/20272; H05K 7/20327; H05K 7/203; H05K 7/20236

(57) ABSTRACT

A method is described. The method includes repeatedly receiving information from one or more sensor circuits that are disposed within a coolant of an immersion cooling system, the one or more sensor circuits to detect one or more contaminants within the coolant. The method includes repeatedly processing the information. The method includes repeatedly keeping the one or more contaminants within acceptable levels within the coolant in response to the information by adjusting a valve setting that affects intake of the coolant to a filtration system of the immersion cooling system, and/or, adjusting a speed of a pump of the filtration system.

### BACKGROUND

Thermal engineers face challenges, particular with respect to high performance computing applications (e.g., centralized cloud computing, consumer graphics and gaming, etc.), as both computers and networks continue to pack higher and higher levels of performance into smaller and smaller packages. Creative cooling solutions are therefore being designed to keep pace with the thermal requirements of such aggressively designed systems.

### BRIEF DESCRIPTION OF THE FIGURES

FIG. 1 shows a cooling system;

FIG. 2 shows an improved cooling system;

FIG. 3 shows byproduct and foreign contaminant curves;

FIG. 4 shows an example of the improved cooling system of FIG. 2 in operation;

FIGS. 5a, 5b and 5c show sensor circuits;

FIGS. 6a and 6b that can be used for sensing materials/electrodes in various sensing circuits;

FIG. 7 shows a high performance computing environment (e.g., a data center);

FIG. 8a shows an infrastructure processing unit (IPU);

FIG. 8b shows a more detailed embodiment of an IPU.

### DETAILED DESCRIPTION OF THE FIGURES

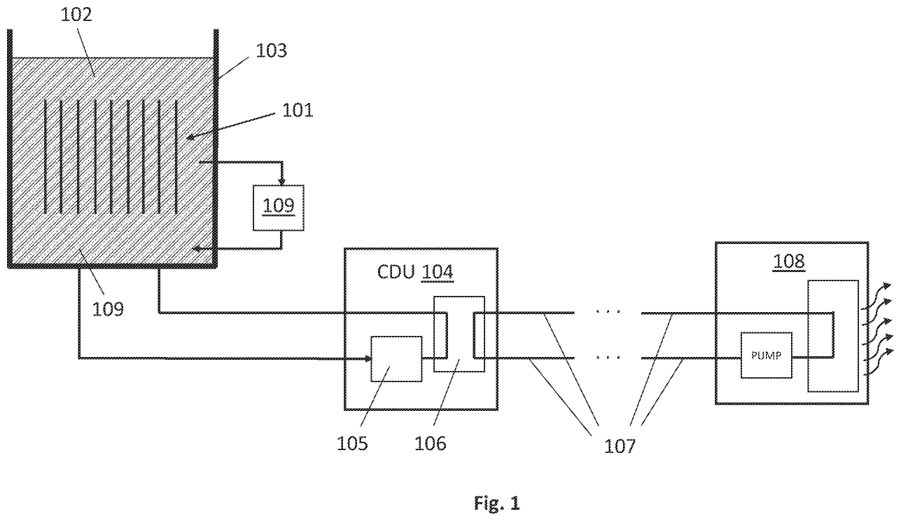

FIG. 1 depicts an immersion cooling system. As observed in FIG. 1, a plurality of electronic circuit boards 101 are immersed in a dielectric liquid 102 that electrically isolates the exposed electrical nodes of the electronic circuit boards 101 and their respective electronic components (FIG. 1 depicts a side view of the circuit boards 101 oriented vertically within the liquid 102). The electronic components, when in operation, generate heat which is transferred to the liquid 102. The liquid 102 has a higher specific heat than air which enables heat to be removed from the electrical components more effectively than would otherwise be achievable in an air-cooled environment.

The immersion bath chamber 103 is fluidically coupled to a coolant distribution unit (CDU) 104 that includes a pump 105 and heat exchanger 106. During continued operation of the electronic components, the liquid's temperature will rise as a consequence of the heat it receives from the operating electronics. The pump 105 draws the warmed liquid 102 from the immersion bath chamber 103 to the heat exchanger 106. The heat exchanger 106 transfers heat from the warmed fluid to secondary liquid within a secondary cooling loop 107 that is fluidically coupled to a cooling tower and/or chilling unit 108. The removal of the heat from the liquid 102 by the heat exchanger 106 reduces the temperature of the liquid which is then returned to the chamber 103 as cooled liquid.

In a high computing environment, such as a data center, the respective CDUs of multiple immersion bath chambers are coupled to the secondary loop 107, and, the cooling tower and/or chilling unit 108 removes the heat generated by the electronics within the multiple immersion bath chambers from the data center.

As described in more detail further below, the dielectric properties or “quality” of the coolant 102 can degrade owing to molecular changes in the coolant over time and/or foreign contaminants that are introduced to the coolant 102 from the electrical components 101 within the coolant 102 and/or the surrounding ambient of the chamber 103. Molecular changes in the coolant 102 can cause the coolant 102 to react with exposed materials of the electronics 101 which produces undesirable byproducts that are themselves a form of contamination.

A filtration system 109 is therefore coupled to the immersion bath chamber 103 to remove the contaminants (byproduct, foreign or both). The filtration system 109 typically includes a filter and a pump. The pumping action of the pump draws coolant 102 within the chamber through the filtration system's filter. The filter traps contaminants within the drawn coolant 102 and the filtered coolant is then returned back to the chamber 103. Over time, the filter's concentration of contaminants increases as it continually (repeatedly) collects contaminants. Eventually, the efficiency of the filter will appreciably decline (e.g., for a fixed flow and contamination level of fluid through the filter, fewer contaminants are trapped).

During the lifetime of the electronics 101, traditionally, the coolant 102 is periodically sampled by hand to ensure the quality of the coolant is within an acceptable range, and, the filtration system's filter is periodically replaced. Notably, the periodic sampling only provides instances of data that are separated by long periods of time and the periodic filter replacement is often based on generic guidelines without any correlation to actual quality levels of the coolant 102. In short, the maintenance of the coolant 102 and filtration system 109 is not based on much insight into the coolant's or filter's real time characteristics.

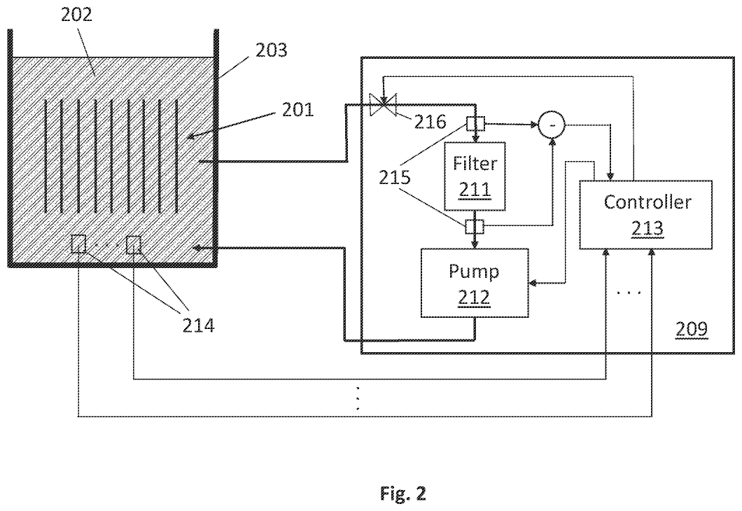

FIG. 2 shows an improved immersion cooling system having a filtration system 209 that continually (repeatedly) monitors the coolant's quality over time and continually (repeatedly) monitors the filter's efficiency over time. With the continuous monitoring of the coolant's quality, confidence that the quality of the coolant remains within acceptable levels is greatly improved, and, with the continuous monitoring of filter efficiency, the timing of filter replacements is better optimized.

Perhaps more importantly, with the continuous monitoring of both coolant quality and filter efficiency, the operation of the filtration system 209 can be modulated in real time in direct response to the coolant's actual, current quality levels. Further still, trends in both coolant quality and filter efficiency can be modeled and predicted. Thus, for instance, the optimal moment for a filter change can be precisely scheduled in the future, and/or, a warning that the quality of the coolant will fall below acceptable levels can be predicted with plenty of time in advance to take corrective action before the event occurs.

As observed in FIG. 2, the improved filtration system 209 includes a filter 211, a pump 212 and a controller 213. The improved filtration system also includes one or more sensors 214 within the immersion bath coolant 202 that measure one or more coolant quality parameters. Another one or more sensors 215 (e.g., fluid pressure transducers) measure the pressure difference across the filtration system's filter 211. Here, over time, as the filter 211 traps more and more contaminants, the filter increasingly impedes/resists the flow of coolant (e.g., the filter approaches a state of being “clogged”) and correspondingly removes less and less contaminants for a same volumetric flow of coolant drawn into the filtration system 209 from the immersion bath 202 (filter efficiency declines).

As a consequence of the filter's increased fluidic resistance/impedance, over time, the fluid pressure at the intake to the filter 211 becomes increasingly larger than the fluid pressure at the output of the filter 211. As such, the difference in fluid pressures measured at both the intake and output of the filter 211 can be used to gauge the filter's efficiency, predict future roll-off of filter efficiency and ultimately determine when filter replacement is appropriate.

The sensors 214, 215 are coupled to a controller 213 that controls the filtration system 209. In particular, the controller 213 controls the setting of one or more valves 216 that establish the cross sectional area of fluid flow that can be drawn into the filtration system 209 from the coolant bath 202 and the pumping action (speed) of the filtration system's pump 212. Here, by controlling both the valves 216 and the pumping speed, the controller 213 can precisely establish a volumetric flow rate of coolant into the filtration system 209 from the coolant bath 202.

Here, the higher the volumetric flow rate of coolant through the filtration system 209, the greater the performance of the filtration system 29 (more coolant fluid flows through the filter per unit of time). Thus, in moments when the coolant 202 is of high quality and minimal filtering is sufficient, the controller 213 can set the valves 216 to a more restrictive setting and/or lower the speed of the pump 212 to reduce the volumetric flow through the filter 211. By contrast, in moments when the quality of the coolant 202 is approaching unacceptable levels, the controller 213 can set the valves 216 to a more open setting and/or increase the speed of the pump 212 to increase the volumetric flow of the cooling fluid through the filter 211. Moreover, to maintain a stable/constant rate of contaminant removal in the face of filter 211 efficiency degradation, the controller 213 can widen the valve 216 openings and/or increase the speed of the pump 212 to increase the flow rate through the filter 211 over time which compensates for the roll-off in filter efficiency over time.

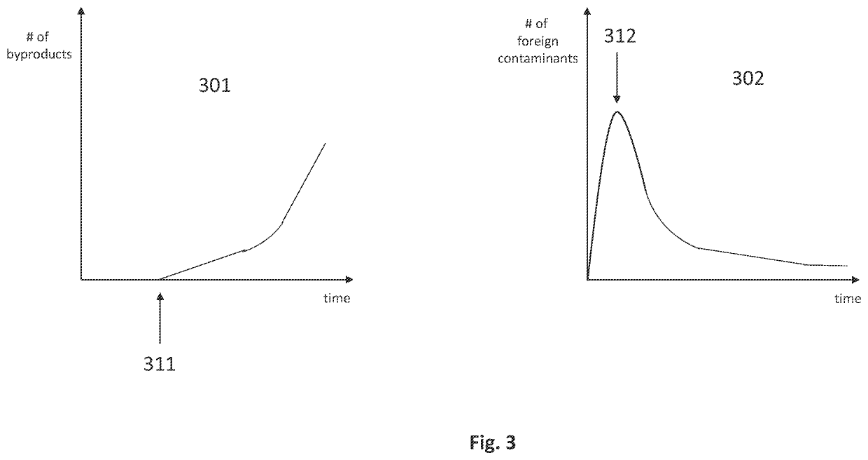

FIG. 3 depicts exemplary coolant quality parameters. As observed in FIG. 3, curve 301 depicts the generation of byproducts within the coolant over time, whereas, curve 302 depicts the concentration of foreign contaminants over time. The time axis for both of curves 301 and 302 start from the moment a chamber's electronics are first powered on and extends forward for a number of days/months thereafter. Notably, the trend observed in curve 301 can transpire over a longer time period than the trend observed in curve 302. Thus the time scales between the curves 301, 302 are not necessarily the same.

With respect to the byproduct generation curve 301, at least for certain types of coolants, the coolant can be damaged at the molecular level (e.g., broken C—H chains) if the electronics 201 that are immersed in the coolant 202 generate large amounts of heat and/or generate large electric fields. The damaged molecules help create byproducts that react with various materials that are present in the exposed surfaces of the electronics 201 which, in turn, can introduce additional foreign particulates into the immersion bath 202. As observed in curve 301, the byproduct concentration is minimal until chemical wear-out of the coolant is induced at time 311, after which, generation of byproducts commences and can even accelerate thereafter.

Referring to curve 302, foreign contaminants are typically sourced from the exposed materials of the electronics that are immersed in the coolant and/or byproducts of chemical interactions with the exposed materials (e.g., zinc whiskers, tin whiskers, etc. from exposed solder, solder flux, exposed chip package I/Os, hydro-peroxide; ketone; carboxylic acid; aldehyde; water (H₂0); hydrocarbon; carbonyl fluoride (e.g., COF₂); hydrogen fluoride (e.g., HF) etc.) and/or the immersion bath chamber's surrounding ambient (concrete dust, smoke, etc.). As observed in curve 302, the foreign contaminant concentration peaks 312 shortly after the electronics are first turned on and then steadily declines to a much lower rate.

Here, just before the electronics are first turned on, various foreign contaminants are loosely attached to the electronics 201 within the bath 202. The foreign contaminants are generally present as a consequence of the manufacturing of the discrete electronic components and/or the attachment of the discrete electronic components to their respective circuit boards and/or the shipping and handling of the components/boards. Other foreign contaminants can also enter the immersion bath 202 by way of the exposure of the inside of the chamber 203 to the outside ambient, e.g., before/during the installation of the electronics 201 within the chamber 203 and/or the addition of the coolant 202 to the chamber 203.

After the electronics are first turned on, many of the foreign contaminants that are loosely attached to the electronics release from the electronics and enter the bath 202 which drives the contaminant concentration upward. After the initial “flush” 312 of foreign contaminants into the bath 202, the release of foreign contaminants into the bath continues but at continually lesser rates until the rate of foreign contaminant introduction to the bath becomes a constant (or nearly a constant).

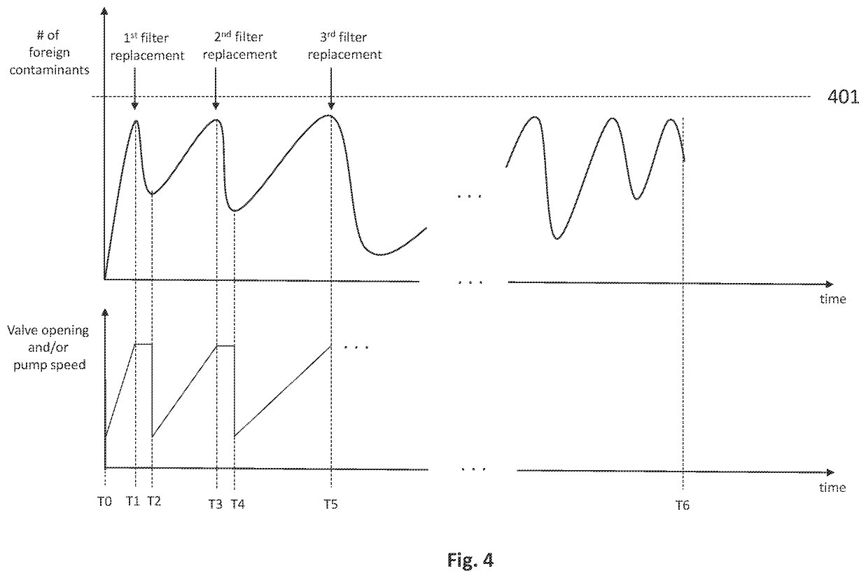

FIG. 4 shows the above described contamination mechanisms within an immersion bath system having the improved filtration system of FIG. 2. Notably, the improved filtration system is to ensure that contamination levels remain beneath a predetermined level to ensure the dielectric properties of the coolant 202 are maintained.

As observed in FIG. 4, as described above with respect to curve 302, shortly after the electronics are first powered on, from time T0 to T1, the concentration of foreign contaminants rapidly increases. Over this time period, the high concentration level of contaminants causes the filter's efficiency to rapidly decline (the filter's fluidic resistance rapidly rises as the filter 211 rapidly traps contaminants).

The controller 213, from time T0 to time T1, senses the rapid rise of contamination in the bath 202 and the decline in the efficiency of the filter 211. In response, from time T0 to time T1, the controller 213 offsets the rapid decline in filter efficiency and maintains the removal of large numbers of contaminants by steadily opening the valves 216 wider and/or increasing the pumping speed of the pump 212. Eventually, as the filter continues to lose efficiency, the contaminant levels begin to approach the maximum allowed concentration 401. As such, the controller 213 schedules a filter replacement at time T1.

Here, from time T0 to time T1, the controller 213 continually senses the contamination levels of the coolant 202 and continually senses the efficiency of the filter 211 to predict the coolant's future contamination levels. Based on these predictions, the controller 213 schedules the replacement of the first filter well in advance of the actual replacement.

After the filter is replaced at time T1, the new highly efficient filter begins to remove the foreign contaminants at a high rate which rapidly lowers the contaminant levels in the coolant bath 202 (the filtration system removes foreign contaminants faster than they enter the bath). Here, the controller 213 can keep or otherwise set the valve openings to a wider setting and/or maintain a high pump speed so that the contamination levels rapidly fall away from the maximum allowed concentration level 401.

By time T2, the concentration levels have sufficiently fallen allowing the controller 213 to reduce the valve openings and/or reduce the pump speed. So doing reduces the rate at which the filtration system removes contaminants from the coolant 202. However, contaminant levels remain well below their allowed maximum 401, and, costs are reduced. With respect to the later (reduced costs), lowering the pump speed reduces the energy consumed by the filtration system 209, and filter lifetime is extended because of the reduced flow rate through the filter (the filter collects fewer contaminants over time as compared to fully open valves and maximum pump speed).

With the reduced rate of contaminant removal, from time T2 to T3, contamination levels begin to rise again owing, e.g., to a decline in filter efficiency and the continued separation of foreign contaminants from the electronics. Notably, however, because foreign contaminants are entering the bath at a reduced rate as compared to immediately after the initial power up of the electronics (as described above with respect to curve 302 of FIG. 3), the rate at which the contamination levels rise from time T2 to time T3 is less than the rate at which contaminant levels rose from time T0 to time T1. As such, the controller 213 is able to widen the valve openings and/or increase pump speed more gradually to offset the second filter's efficiency roll-off than with the first filter's efficiency roll-off.

Again, from time T2 to time T3, the controller 213 continually senses the contamination levels of the coolant 202 and continually senses the efficiency of the filter 211 to predict the coolant's future contamination levels. Based on these predictions, the controller 213 schedules the replacement of the second filter well in advance of the actual replacement.

After the second filter is replaced at time T3, the new (third) highly efficient filter begins to remove the foreign contaminants at a high rate. Essentially, the process described above for the second filter repeats itself, but with even further reductions in contaminant concentration levels. Here, the continued operation of the filtration system 209 from time TO to T3 has caused the removal of substantial amounts of the foreign contaminants that were initially released into the coolant bath 202 after the initial power on of the electronics combined with the continued introduction of foreign contaminants into the bath. As such, the contamination level falls to a new low around time T4.

At time T4, commensurate with the new low in contamination levels, the controller is again able to reduce the valve openings and/or the pump speed. From time T4 to time T5, contaminant levels begin to rise upward again but, because of the lower contamination levels, at a lower rate than between times TO and T1 and between times T2 and T3. Thus, the controller 213 is able to offset the efficiency roll-off of the third filter with even more gradual valve openings and pump speed increases than with the second filter. The reduced contamination levels and more gradual pump speed increases corresponds to a longer filter lifetime and greater cost savings with the third filter than with the second filter.

Again, from time T4 to time T5, the controller 213 continually senses the contamination levels of the coolant 202 and continually senses the efficiency of the filter 211 to predict the coolant's future contamination levels. Based on these predictions, the controller 213 schedules the replacement of the third filter well in advance of the actual replacement.

The processes described above continue such that, with each next filter, lower absolute contaminant levels are achieved with longer filter lifetimes. Eventually, a quasi steady state can be reached where, with each next filter, minimum achieved contaminant levels and filer lifetimes remains approximately constant.

Eventually, however, the coolant begins to wear out and the processes described above begin to reverse. Here, as described above with respect to curve 301 of FIG. 3, as the coolant wears out byproducts are produced that react with exposed surface materials of the electronics 201, which, in turn, generates more foreign contaminants into the immersion bath 202. The rate at which foreign contaminants are introduced into the bath 202 therefore increases over time as coolant wear out accelerates.

Thus, over time, contamination levels rise more rapidly and filter changes become more frequent. The controller continues to model future contamination levels and filter efficiencies and eventually predicts when the filtration system 209 cannot keep contamination levels below the maximum allowed level 401. Well in advance of this event, however, the controller 213 is able to raise an alarm and schedule a change of the coolant 202.

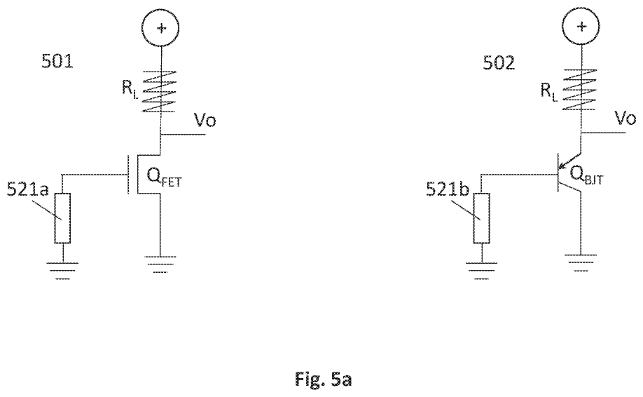

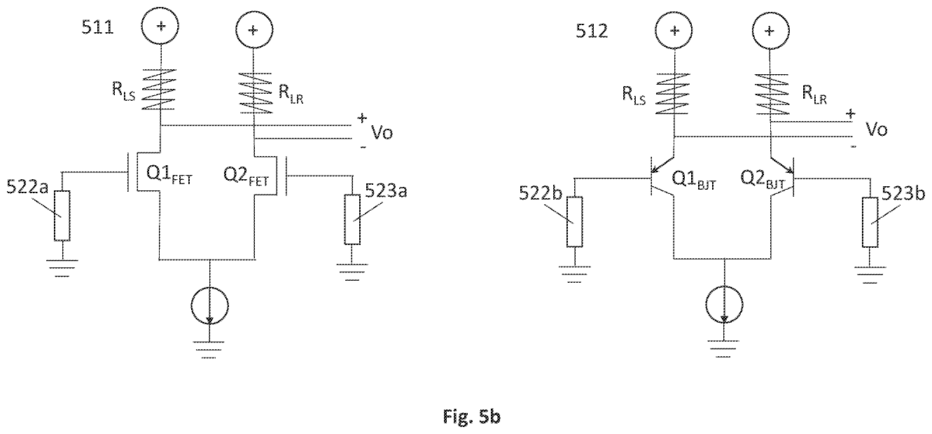

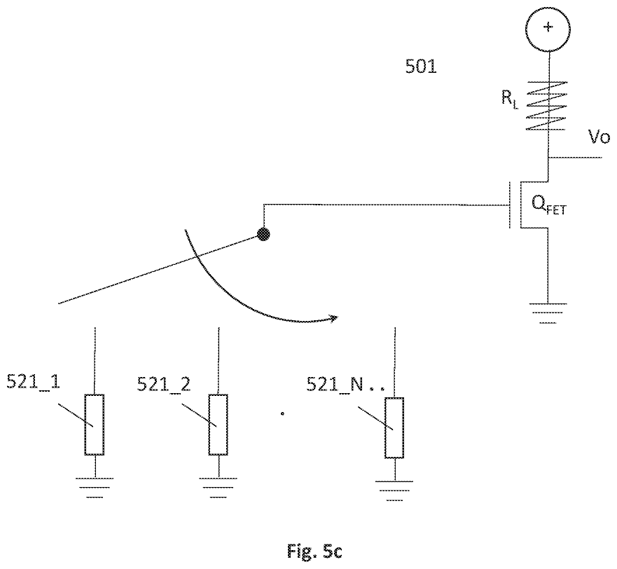

FIGS. 5a and 5b show various coolant quality sensor embodiments. As observed in FIGS. 5a and 5b, a coolant quality sensor can be implemented with one or two transistors (or more for, e.g., more precision or dynamic range), where, a node of a transistor is coupled to a material 521, 522 (e.g., a metal or alloy) that chemically reacts with one or more certain contaminants in the immersion bath resulting in an electrical property change in the material 521, 522.

For example, depending on the material, the contaminant and the reaction, the material 521, 522 may develop a positive voltage, a negative voltage, a higher resistance or a lower resistance. The operating point of the transistor Q_{FET}, Q1_{FET} that is coupled to the material 521, 522 changes in response to the material's electrical property changes. The change in the transistor's operating point is detected and interpreted into a measurement of the contaminant that the material 521, 522 is reacting with.

In the case of the FET sensor 501 of FIG. 5a, if the material 521a generates a change in voltage potential as a consequence of a reaction, the change in voltage potential changes the FET's gate voltage which, in turn, causes the FET Q FET to pull more or less current through the load resistor R_{L} (depending on the polarity of the voltage change). The voltage change across the load resistor R_{L} is detected and interpreted into a measurement of the contaminant.

Likewise, in the case of the BJT sensor 502 of FIG. 5b, if the material 521b generates a change in electrical resistance as a consequence of a reaction with a particular one or more contaminants, the change in resistance causes more or less current to flow through the base node of the transistor (depending on the polarity of the resistance change) which, in turn, causes the BJT Q1_{BJT} to pull more or less current through the load resistor R_{L}. Again, the voltage change across the load resistor R_{L} is detected and interpreted into a measurement of the contaminant(s).

The sensors 511, 512 of FIG. 5b are designed to detect a difference between an electrical property of a sensing material 522 that changes as a consequence of its reaction with a contaminant as described above, and, a same electrical property of a reference material 523 that, ideally, does not endure any reactions nor electrical property changes.

Here, with respect to sensor 511, transistors Q1_{FET} and Q2_{FET} will pull different currents if the sensor material 522a exhibits an electrical voltage change in response to its reaction with contaminants that the reference material 523a does not exhibit. The different currents pulled by transistors Q1_{FET}, Q2_{FET} creates a voltage difference between the sensing and reference load resistances R_{LS} and R_{LR} that is interpreted into a measure of the contaminants. With respect to sensor 512, transistors Q1_{BJT} and Q2_{BJT} will pull different currents if the sensor material 522b exhibits an electrical resistance change in response to its reaction with contaminants that the reference material 523b does not exhibit. The different currents pulled by transistors Q1_{BJT}, Q2_{BJT} creates a voltage difference between the sensing and reference load resistances R_{LS} and R_{LR} that is interpreted into a measure of the contaminants.

FIG. 5c shows that different sensor materials can be multiplexed into a same transistor/sensor circuit. These designs allow a single transistor/circuit to be used to measure a multitude of different contaminants (e.g., each different sensor material is used to detect a different type contaminant). Depending on the sensor materials that are used and the strength of their respective electrical changes in response to their respective reactions, different load resistors can also be multiplexed into the circuit to, e.g., handle a large dynamic range of sensor material signals (e.g., up to and including 10⁴, up to and including 10⁵, etc.). For illustrative ease, multiplexing of the load resistances is not depicted in the approach of FIG. 5c.

For illustrative ease, only the single transistor FET circuit of FIG. 5a is used as an example in FIG. 5c. However, any of the circuits of FIGS. 5a and 5b can adopt the multiplexed approach of FIG. 5c. The reference material of the differential circuits of FIG. 5b can also multiplex different reference materials if a specific reference is to be pair with a specific sensor material, or, a “common” reference can be used for multiple sensor materials which negates multiplexing with the reference signal.

In various embodiments of the sensing circuits of FIGS. 5a through 5c, the entire sensing circuit is placed in the immersion bath. In differential embodiments as in FIG. 5b, if the reference material 523a,b is the same material as the sensing material 522a,b but is placed in contaminant free (or near contaminant free) coolant to establish the reference, the reference material 523a,b and the contaminant free coolant can be located outside the immersion chamber. Alternatively, the contaminant free coolant and reference material can be sealed within a hermetically sealed package that is inserted into the immersion bath. The hermetically sealed package isolates the contaminant free (reference) coolant from the actual coolant within the chamber.

As is known in the art, there are different types of immersion cooling systems. A first kind, described above with respect to FIG. 1, is referred to as “single-phase” cooling. In the case of single-phase cooling, the immersed electronics are cooled by convection cooling of the liquid coolant within the chamber (heat is transferred from the electronics to the moving coolant within the chamber).

Another type of immersion cooling system, referred to as “two-phase”, uses convection cooling and evaporation to remove heat from the electronics. In the case of two-phase cooling, when the electronics are dissipating modest amounts of heat, the electronics are cooled by convection cooling as in single-phase cooling described above. When the electronics dissipating larger amounts of heat, the heat absorbed by the liquid coolant causes the temperature of the liquid coolant to surpass its boiling point and the liquid coolant boils. The evaporated (gas phase) liquid rises above the liquid within the chamber where a condenser that is placed in the space above the liquid within the chamber cools the gas and condenses it back into a liquid. Here, cool water is pumped into the condenser. As heat is transferred from the gaseous phase coolant to the water within the condenser, the water within the condenser is warmed and then pumped out of the condenser while the cooled gas particles of coolant transition to a liquid phase and fall back into the immersion bath.

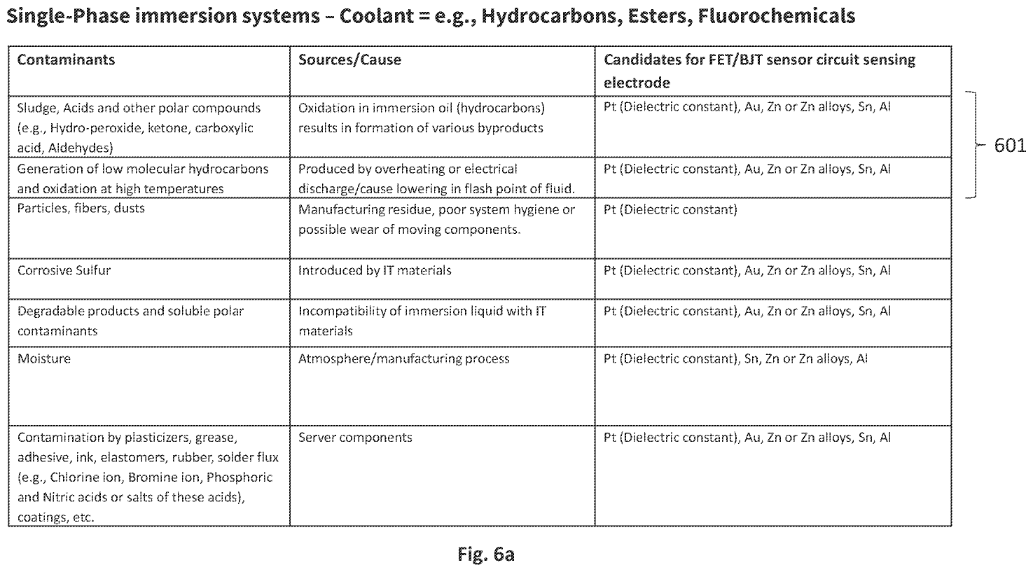

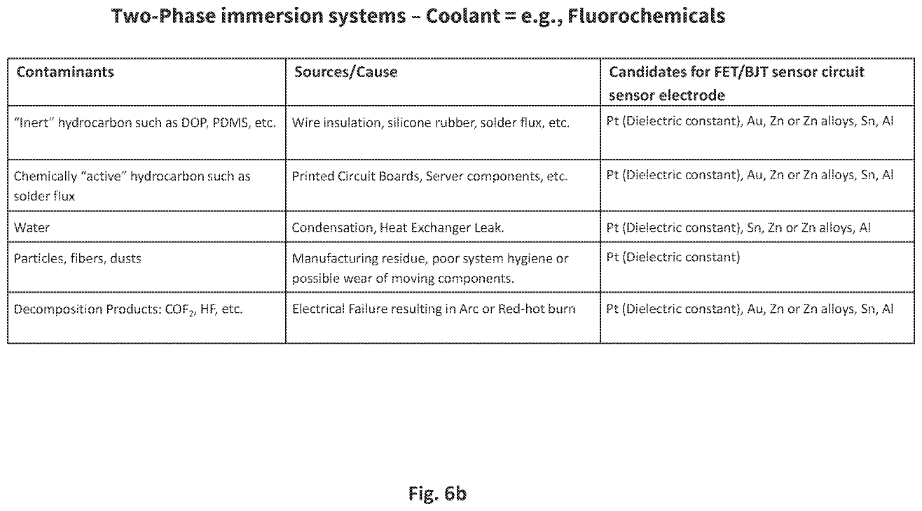

FIGS. 6a and 6b show tables for the types of contaminants that can be found in single-phase (FIG. 6a) and two-phase (FIG. 6b) immersion coolants, and, corresponding materials that can be used for the sensing electrode 521, 522 of the above described sensor circuits of FIGS. 5a through 5c to detect the presence of the particular contaminants. Note that, in FIG. 6a, the first two entries 601 are associated with the byproduct formation described above with respect to curve 301 of FIG. 3, whereas, the remainder of the entries are associated with the foreign contaminants curve 302 of FIG. 3. As observed in FIG. 6a, the sensing electrode 521, 522 can generally be composed of any of Gold (Au), Zinc (Zn), Tin (Sn), Aluminum (Al) or alloys of these.

Apart from the detection of specific contaminants, sensor circuits like those described above with respect to FIGS. 5a through 5c, or other sensor circuits, can be used to characterize a specific coolant quality parametric rather than detecting the presence of a specific contaminant. For example, as observed in FIGS. 6a and 6b, Platinum (Pt) can be used for the sensing electrode for a sensing circuit that measures the dielectric constant of the coolant.

Other coolant quality parametrics that can be tested include: 1) the dielectric breakdown voltage and/or current “leakage” of the coolant (e.g., with a circuit that pumps up the voltage across two electrodes until breakdown occurs and/or measures current between the two electrodes); 2) the coolant's electrical resistivity (e.g., with a circuit that applies a voltage across two electrodes and measures current between the two electrodes); and, 3) the temperature of the coolant (e.g., with a thermocouple circuit). With respect to the latter (temperature measurement), coolant wear-out can be accelerated with higher coolant temperatures and thus can at least be viewed or correlated as a coolant quality parametric.

Any/all of the sensors described above can be immersed in the coolant 202 of the system of FIG. 2 and their respective outputs provided to the controller 213. Thus, for instance, a single implementation can include: 1) multiple sensors to detect specific respective contaminants; 2) pressure transducer sensors to measure the pressure difference between the filter input/output so that filter efficiency can be gauged; 3) one or more sensors to detect the coolant's dielectric breakdown voltage; 4) one or more sensors to detect the coolant's resistivity; 5) one or more sensors to detect the coolant's temperature.

With this comprehensive analysis of the state of the coolant being continuously fed to the controller 213, the controller 213 can execute sophisticated models that, e.g., modulate the filtration system's valves and/or pump speed to keep the quality of the coolant acceptable (e.g., the controller 213 executes a control loop that drives coolant quality and/or contamination level to a specific “set point”), predict when filter replacement will be appropriate, predict when coolant replacement will be appropriate, etc.

The controller 213 can be implemented, e.g., with hardware (electronic circuitry), software or any combination of hardware and software. As just one example, the controller's models are implemented in software that execute on one or more processors.

In various embodiments, the controller 213 employs artificial intelligence to run the filtration system 209 and schedule filter/coolant replacements. For example, over an extended period of time the controller 213 can execute machine learning algorithms by observing the measured data from the immersion bath 202 in response to specific filtration system settings and workload parameters of the operating electronics within the coolant 202.

The machine learning is aimed at assigning weights to the connections between nodes within a neural network (which can be implemented in hardware, software or any combination of hardware and software). Once the weights are verified, they are applied to the neural network and the controller 213 thereafter applies the data that is sensed from the immersion tank (and, e.g., the workload of the electronics) to the neural network which provides inferences of the appropriate filtration system valve and pump settings for the current state of the coolant and the electronics workload.

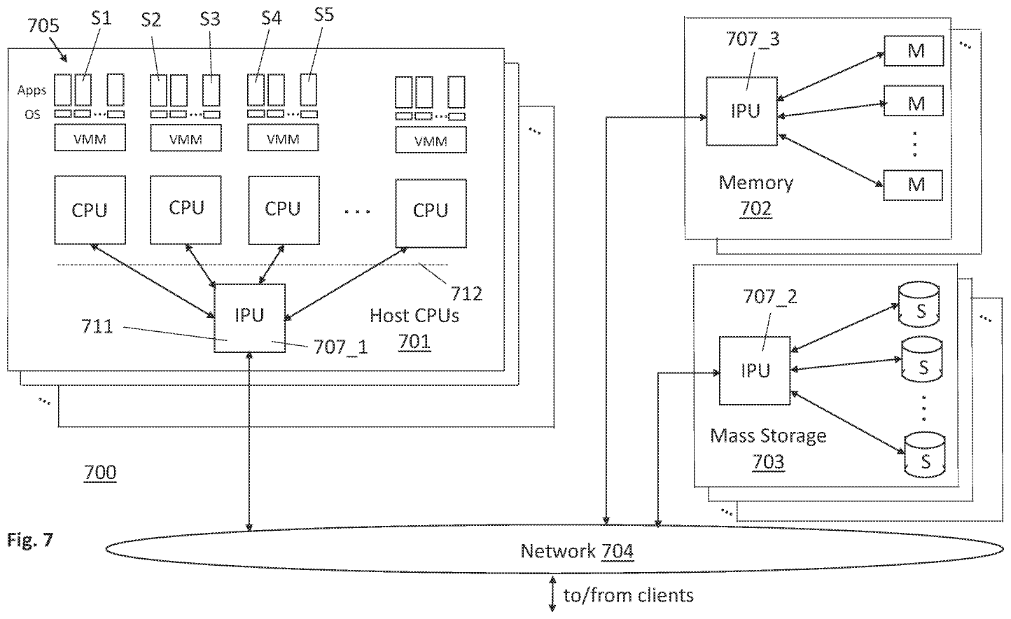

FIG. 7 shows a new, emerging data center environment in which “infrastructure” tasks are offloaded from traditional general purpose “host” CPUs (where application software programs are executed) to an infrastructure processing unit (IPU) or data processing unit (DPU) any/all of which are hereafter referred to as an IPU.

Networked based computer services, such as those provided by cloud services and/or large enterprise data centers, commonly execute application software programs for remote clients. Here, the application software programs typically execute a specific (e.g., “business”) end-function (e.g., customer servicing, purchasing, supply-chain management, email, etc.). Remote clients invoke/use these applications through temporary network sessions/connections that are established by the data center between the clients and the applications. A recent trend is to strip down the functionality of at least some of the applications into more finer grained, atomic functions (“micro-services”) that are called by client programs as needed. Micro-services typically strive to charge the client/customers based on their actual usage (function call invocations) of a micro-service application.

In order to support the network sessions and/or the applications' functionality, however, certain underlying computationally intensive and/or trafficking intensive functions (“infrastructure” functions) are performed.

Examples of infrastructure functions include routing layer functions (e.g., IP routing), transport layer protocol functions (e.g., TCP), encryption/decryption for secure network connections, compression/decompression for smaller footprint data storage and/or network communications, virtual networking between clients and applications and/or between applications, packet processing, ingress/egress queuing of the networking traffic between clients and applications and/or between applications, ingress/egress queueing of the command/response traffic between the applications and mass storage devices, error checking (including checksum calculations to ensure data integrity), distributed computing remote memory access functions, etc.

Traditionally, these infrastructure functions have been performed by the CPU units “beneath” their end-function applications. However, the intensity of the infrastructure functions has begun to affect the ability of the CPUs to perform their end-function applications in a timely manner relative to the expectations of the clients, and/or, perform their end-functions in a power efficient manner relative to the expectations of data center operators.

As such, as observed in FIG. 7, the infrastructure functions are being migrated to an infrastructure processing unit (IPU) 707. FIG. 7 depicts an exemplary data center environment 700 that integrates IPUs 707 to offload infrastructure functions from the host CPUs 704 as described above.

As observed in FIG. 7, the exemplary data center environment 700 includes pools 701 of CPU units that execute the end-function application software programs 705 that are typically invoked by remotely calling clients. The data center also includes separate memory pools 702 and mass storage pools 705 to assist the executing applications. The CPU, memory storage and mass storage pools 701, 702, 703 are respectively coupled by one or more networks 704.

Notably, each pool 701, 702, 703 has an IPU 707_1, 707_2, 707_3 on its front end or network side. Here, each IPU 707 performs pre-configured infrastructure functions on the inbound (request) packets it receives from the network 704 before delivering the requests to its respective pool's end function (e.g., executing application software in the case of the CPU pool 701, memory in the case of memory pool 702 and storage in the case of mass storage pool 703).

As the end functions send certain communications into the network 704, the IPU 707 performs pre-configured infrastructure functions on the outbound communications before transmitting them into the network 704. The communication 712 between the IPU 707_1 and the CPUs in the CPU pool 701 can transpire through a network (e.g., a multi-nodal hop Ethernet network) and/or more direct channels (e.g., point-to-point links) such as Compute Express Link (CXL), Advanced Extensible Interface (AXI), Open Coherent Accelerator Processor Interface (OpenCAPI), Gen-Z, etc.

Depending on implementation, one or more CPU pools 701, memory pools 702, mass storage pools 703 and network 704 can exist within a single chassis, e.g., as a traditional rack mounted computing system (e.g., server computer). In a disaggregated computing system implementation, one or more CPU pools 701, memory pools 702, and mass storage pools 703 are separate rack mountable units (e.g., rack mountable CPU units, rack mountable memory units (M), rack mountable mass storage units (S)).

In various embodiments, the software platform on which the applications 705 are executed include a virtual machine monitor (VMM), or hypervisor, that instantiates multiple virtual machines (VMs). Operating system (OS) instances respectively execute on the VMs and the applications execute on the OS instances. Alternatively or combined, container engines (e.g., Kubernetes container engines) respectively execute on the OS instances. The container engines provide virtualized OS instances and containers respectively execute on the virtualized OS instances. The containers provide isolated execution environment for a suite of applications which can include, applications for micro-services.

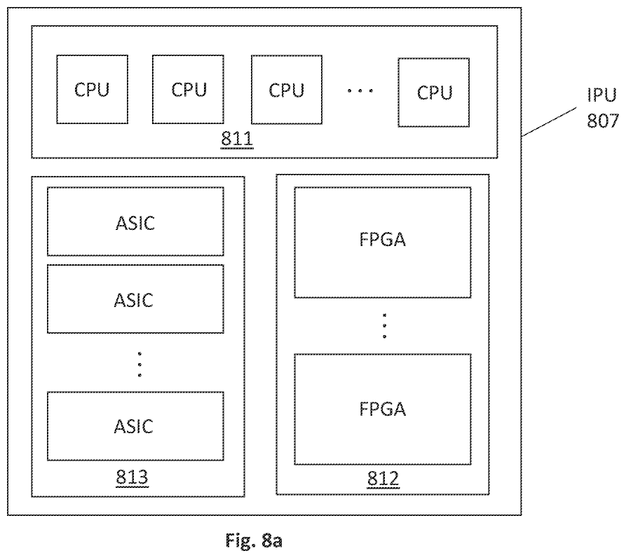

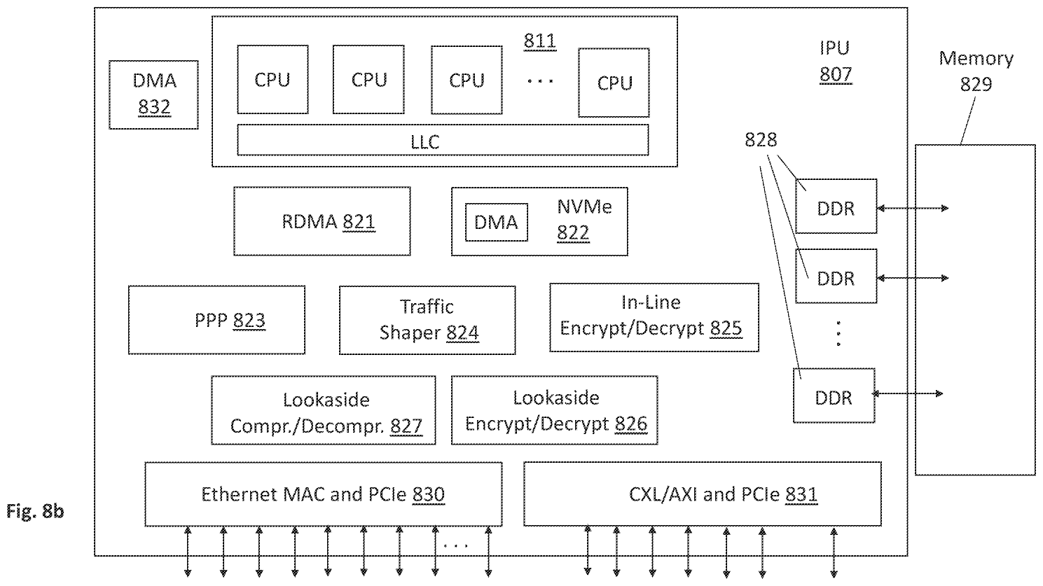

FIG. 8a shows an exemplary IPU 807. As observed in FIG. 8 the IPU 807 includes a plurality of general purpose processing cores 811, one or more field programmable gate arrays (FPGAs) 812, and/or, one or more acceleration hardware (ASIC) blocks 813. An IPU typically has at least one associated machine readable medium to store software that is to execute on the processing cores 811 and firmware to program the FPGAs (if present) so that the processing cores 811 and FPGAs 812 (if present) can perform their intended functions.

The IPU 807 can be implemented with: 1) e.g., a single silicon chip that integrates any/all of cores 811, FPGAs 812, ASIC blocks 813 on the same chip; 2) a single silicon chip package that integrates any/all of cores 811, FPGAs 812, ASIC blocks 813 on more than chip within the chip package; and/or, 3) e.g., a rack mountable system having multiple semiconductor chip packages mounted on a printed circuit board (PCB) where any/all of cores 811, FPGAs 812, ASIC blocks 813 are integrated on the respective semiconductor chips within the multiple chip packages.

The processing cores 811, FPGAs 812 and ASIC blocks 813 represent different tradeoffs between versatility/programmability, computational performance and power consumption. Generally, a task can be performed faster in an ASIC block and with minimal power consumption, however, an ASIC block is a fixed function unit that can only perform the functions its electronic circuitry has been specifically designed to perform.

The general purpose processing cores 811, by contrast, will perform their tasks slower and with more power consumption but can be programmed to perform a wide variety of different functions (via the execution of software programs). Here, the general purpose processing cores can be complex instruction set (CISC) or reduced instruction set (RISC) CPUs or a combination of CISC and RISC processors.

The FPGA(s) 812 provide for more programming capability than an ASIC block but less programming capability than the general purpose cores 811, while, at the same time, providing for more processing performance capability than the general purpose cores 811 but less than processing performing capability than an ASIC block.

FIG. 8b shows a more specific embodiment of an IPU 807. The particular IPU 807 of FIG. 8b does not include any FPGA blocks. As observed in FIG. 8b the IPU 807 includes a plurality of general purpose cores 811 and a last level caching layer for the general purpose cores 811. The IPU 807 also includes a number of hardware ASIC acceleration blocks including: 1) an RDMA acceleration ASIC block 821 that performs RDMA protocol operations in hardware; 2) an NVMe acceleration ASIC block 822 that performs NVMe protocol operations in hardware; 3) a packet processing pipeline ASIC block 823 that parses ingress packet header content, e.g., to assign flows to the ingress packets, perform network address translation, etc.; 4) a traffic shaper 824 to assign ingress packets to appropriate queues for subsequent processing by the IPU 807; 5) an in-line cryptographic ASIC block 825 that performs decryption on ingress packets and encryption on egress packets; 6) a lookaside cryptographic ASIC block 826 that performs encryption/decryption on blocks of data, e.g., as requested by a host CPU 301; 7) a lookaside compression ASIC block 827 that performs compression/decompression on blocks of data, e.g., as requested by a host CPU 701; 8) checksum/cyclic-redundancy-check (CRC) calculations (e.g., for NVMe/TCP data digests and/or NVMe DIF/DIX data integrity); 9) thread local storage (TLS) processes; etc.

So constructed/configured, the IPU can be used to perform routing functions between endpoints within a same pool (e.g., between different host CPUs within CPU pool 701) and/or routing within the network 704. In the case of the latter, the boundary between the network 704 and the IPU's pool can reside within the IPU, and/or, the IPU is deemed a gateway edge of the network 704.

The IPU 807 also includes multiple memory channel interfaces 828 to couple to external memory 829 that is used to store instructions for the general purpose cores 811 and input/output data for the IPU cores 811 and each of the ASIC blocks 821-826. The IPU includes multiple PCIe physical interfaces and an Ethernet Media Access Control block 830, and/or more direct channel interfaces (e.g., CXL and or AXI over PCIe) 831, to support communication to/from the IPU 807. The IPU 807 also includes a DMA ASIC block 832 to effect direct memory access transfers with, e.g., a memory pool 702, local memory of the host CPUs in a CPU pool 701, etc. As mentioned above, the IPU 807 can be a semiconductor chip, a plurality of semiconductor chips integrated within a same chip package, a plurality of semiconductor chips integrated in multiple chip packages integrated on a same module or card, etc.

Notably, the electronics used to implement any of the pools described above with respect to FIG. 7, and/or, any of the respective components within these pools, including any IPUs having features described above with respect to FIGS. 8a and 8b, can be immersed in an immersion bath 202 and cooled by the improved filtration system 209 described at length above.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable storage medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A method, comprising:
repeatedly receiving information from one or more sensor circuits that are disposed within a coolant of an immersion cooling system, the one or more sensor circuits to detect one or more contaminants within the coolant;
repeatedly processing the information; and,
repeatedly keeping the one or more contaminants within acceptable levels within the coolant in response to the information by adjusting a valve setting that affects intake of the coolant to a filtration system of the immersion cooling system, and/or, adjusting a speed of a pump of the filtration system.

2. The method of claim 1 further comprising continually processing the information to schedule a change of a filter of the filtration system.

3. The method of claim 1 wherein the information includes additional information collected from an additional one or more sensors within the coolant that measure:
the coolant's temperature;
the coolant's resistivity;
the coolant's dielectric constant;
the coolant's dielectric breakdown voltage; and/or
a leakage current of the coolant.

4. The method of claim 3 wherein the additional one or more sensors comprise platinum coupled to a transistor to detect the coolant's dielectric constant.

5. The method of claim 1 wherein the processing further comprises applying a model to the information when the respective levels of the one or more contaminants are rising to determine when a filter of the filtration system should be changed.

6. The method of claim 1 wherein the one or more contaminants include:
hydro-peroxide;
ketone;
carboxylic acid;
an aldehyde;
H₂0;
solder flux;
hydrocarbon;
carbonyl fluoride (COF₂); and/or,
hydrogen fluoride.

7. The method of claim 1 wherein the one or more sensor circuits comprise a sensing material coupled to a transistor, and wherein, the sensing material is comprised of an element selected from the group consisting of:
Gold;
Zinc;
Tin;
Aluminum.

8. A machine readable storage medium containing program code that when processed by one or more processors of a filtration system of an immersion cooling system causes the one or more processors to perform a method, comprising:
repeatedly receiving information from one or more sensor circuits that are disposed within a coolant of the immersion cooling system, the one or more sensor circuits to detect one or more contaminants within the coolant;
repeatedly processing the information; and,
repeatedly keeping the one or more contaminants within acceptable levels within the coolant in response to the information by adjusting a valve setting that affects intake of the coolant to the filtration system, and/or, adjusting a speed of a pump of the filtration system.

9. The machine readable storage medium of claim 8 further comprising repeatedly processing the information to schedule a change of a filter of the filtration system.

10. The machine readable storage medium of claim 8 wherein the information includes additional information collected from an additional one or more sensors within the coolant that measure:
the coolant's temperature;
the coolant's resistivity;
the coolant's dielectric constant;
the coolant's dielectric breakdown voltage; and/or
a leakage current of the coolant.

11. The machine readable storage medium of claim 10 wherein the additional one or more sensors comprise platinum coupled to a transistor to detect the coolant's dielectric constant.

12. The machine readable storage medium of claim 8 wherein the processing further comprises applying a model to the information when the respective levels of the one or more contaminants are rising to determine when a filter of the filtration system should be changed.

13. The machine readable storage medium of claim 8 wherein the one or more contaminants include:
hydro-peroxide;
ketone;
carboxylic acid;
an aldehyde;
H₂0;
solder flux;
hydrocarbon;
carbonyl fluoride (COF₂); and/or,
hydrogen fluoride.

14. The machine readable storage medium of claim 8 wherein the one or more sensor circuits comprise a sensing material coupled to a transistor, and wherein, the sensing material is comprised of an element selected from the group consisting of:
Gold;
Zinc;
Tin;
Aluminum.

15. An apparatus, comprising:
one or more sensor circuits to be disposed within a coolant of an immersion cooling system, the one or more sensor circuits to detect one or more contaminants within the coolant;
a valve to affect intake of the coolant to a filtration system of the immersion cooling system;
a pump to pump coolant within the filtration system through a filter of the filtration system; and,
a controller to repeatedly receive information from the one or more sensor circuits and repeatedly keep the one or more contaminants within acceptable levels within the coolant in response to the information by adjusting a setting of the valve, and/or, a speed of the pump.

16. The apparatus of claim 15 wherein the controller is to process the information to schedule a change of a filter of the filtration system.

17. The apparatus of claim 15 wherein the information includes additional information collected from an additional one or more sensors within the coolant that measure:
the coolant's temperature;
the coolant's resistivity;
the coolant's dielectric constant;
the coolant's dielectric breakdown voltage; and/or
a leakage current of the coolant.

18. The apparatus of claim 17 wherein the additional one or more sensors comprise platinum coupled to a transistor to detect the coolant's dielectric constant.

19. The apparatus of claim 15 wherein the controller is to apply a model to the information when the respective levels of the one or more contaminants are rising to determine when a filter of the filtration system should be changed.

20. The apparatus of claim 15 wherein the one or more contaminants include:
hydro-peroxide;
ketone;
carboxylic acid;
an aldehyde;
H₂0;
solder flux;
hydrocarbon;
carbonyl fluoride (COF₂); and/or,
hydrogen fluoride.
